(19) United States
(12) Patent Application Publication
(10) Pub. No.: US 2026/0171342 A1
(43) Pub. Date: Jun. 18, 2026

(54) ELECTRON EMISSION SOURCE

(71) Applicant: INFOVION INC., Bucheon-si (KR)

(72) Inventors: Yong Hwan KIM, Goyang-si (KR); Yong Ki LEE, Seoul (KR)

(21) Appl. No.: 19/125,732

(22) PCT Filed: Nov. 7, 2023
(86) PCT No.: PCT/KR2023/017781

§ 371 Date: Apr. 29, 2025

(30) Foreign Application Priority Data
Nov. 16, 2022 (KR) 10-2022-0153269

(51) Int. Cl. H01J 1/304; H01J 3/02; H01J 31/12; H01J 37/08

(52) U.S. Cl. CPC H01J 1/304; H01J 3/022; H01J 31/127; H01J 37/08

(57) ABSTRACT

Provided is an electron emission source. The electron emission source comprises: a housing provided with a gas inlet pipe for introducing an inert gas into an internal space for plasma generation; a cathode electrode having a hemispherical shape and being made of a metallic material; a power supply unit connected to the cathode electrode and configured to apply a combination of RF power and DC power; and an anode electrode having an internal space formed in a conical shape, being made of a ceramic dielectric material, including an electron emission port at the apex of the conical shape, and having the internal space function as a plasma chamber. The electron emission source generates a capacitively coupled plasma (CCP) in the plasma chamber by supplying RF power to the cathode electrode, and emits electrons through the electron emission port of the anode electrode using the CCP.

### TECHNICAL FIELD

The present invention relates to an electron emission source and, more particularly, to an electron emission source employing CCP plasma, wherein the structures of a cathode electrode and an anode electrode are newly designed, and the constituent material of the anode electrode is modified so as to enable stable and prolonged generation of an electron beam.

### BACKGROUND ART

During semiconductor device and thin film fabrication processes, ion beams carrying positive charges are irradiated onto a target or substrate made of an insulator or semiconductor for various purposes.

FIG. 1 is a schematic diagram illustrating a neutralization process using an electron emission source during irradiation of an ion beam onto a target or substrate according to conventional techniques. As shown in FIG. 1, when the ion beam is irradiated onto a target or substrate, the positive charges of the ion beam accumulate on the surface of the target or substrate, which is made of an insulator or semiconductor.

On the other hand, in the case where negative charges accumulate, the electron particles constituting the negative charges naturally flow toward the surface, thereby neutralizing the accumulated charges. However, when positive charges accumulate, they cannot be self-neutralized unless additional electrons are supplied to fill the electron-deficient regions.

Accordingly, when the positive charges of the ion beam accumulate on the surface of the target or substrate, the charges are not self-neutralized and continue to build up at the surface protrusions of the material. When such positive charging occurs on the surface of an insulating target or substrate, the accumulated charge eventually discharges, resulting in surface micro-arcing. As a result, at the point of arc generation on the target or substrate irradiated with the ion beam, surface defects resembling a volcanic eruption may occur, thereby causing a serious problem.

In order to resolve the aforementioned problem, the ion beam is neutralized during irradiation onto the surface of the target or substrate, thereby eliminating the positive charge accumulation. The neutralization process of the ion beam involves irradiating an electron beam into the space through which the ion beam travels during the ion beam irradiation onto the target or substrate. The irradiated electron beam follows the ion beam and reaches the positively charged area on the surface of the target or substrate. The accumulated positive charges on the surface are neutralized by combining with the negative charges of the electrons. The electron emission source is a device configured to generate and emit electrons and may be utilized for neutralizing the ion beam.

Conventionally, the electron emission source is positioned on one side of the line along which the ion beam is irradiated and travels. Electrons emitted from the electron emission source travel toward the substrate in parallel with the ion beam, following the flow of the ion beam. As a result, the electrons combine with the positive charges accumulated on the substrate, thereby achieving charge neutralization.

Meanwhile, when the positive charges of the ion beam become dispersed throughout the space in which the ion beam travels, repulsive forces are generated among the spatially distributed positive charges. When electrons are introduced into this space, the electrons become dispersed between the positively charged ions, and the presence of these dispersed electrons offsets the repulsive forces among the positive charges of the ion beam. This phenomenon, in which mutual repulsion among charged particles causes the ion beam to spread at a wider angle during flight, is referred to as the space charge effect. Through the neutralization of the ion beam by electrons, the space charge effect is suppressed, thereby contributing to the straight-line propagation of the ion beam.

Meanwhile, conventional electron emission sources use tungsten (W) filaments. Accordingly, the conventional electron emission source has the form of an electron gun, in which the filament is heated to emit thermal electrons that exceed the work function of the filament surface, and the electrons are further accelerated and emitted by applying a negative voltage to the filament. However, such electron gun-type electron emission sources suffer from degradation of the filament due to heating, resulting in frequent breakage of the filament. As a result, the conventional electron emission source has the inconvenient problem of requiring frequent filament replacement. In addition, the conventional electron emission source causes another problem in that the filament acts as a source of contamination, as it undergoes sputter etching due to collisions with gas ions.

In order to overcome the limitations of electron emission sources that use filaments, conventional technologies have employed electron emission sources based on Inductively Coupled Plasma (ICP) driven by an RF power source, enabling long-term operation. The conventional ICP electron emission source using RF power is typically manufactured in a compact form, smaller in size than the ion beam source, serving as an auxiliary device to the ion beam source. Therefore, the conventional ICP electron emission source must use a small ICP antenna having an outer diameter of approximately 20 to 50 mm. Due to the use of such the small and thin antenna, it becomes impossible to circulate cooling water through the antenna, resulting in degradation of the antenna. In addition, in the absence of a cooling function for the ICP coil antenna, a rise in the temperature of the antenna coil causes RF matching to be disrupted, which in turn leads to the extinguishment of the plasma. Therefore, in order to achieve a compact structure that does not require cooling water circulation, it has been necessary to overcome the problems inherent in ICP coils.

In addition, the electron emission source must satisfy an electric optic structure in which electrons are electrically extracted for emission of electron particles. Accordingly, a miniaturized RF matching box is used. Due to the use of such a miniaturized RF matching box, heat is generated inside the electron emission source and the matching box, and internal contamination becomes severe, frequently resulting in disrupting the RF matching. The matching box, being miniaturized, exhibits electrical and structural fragility, thereby making it difficult to ensure reliable operation under repeated activation. As a result of these problems, conventional electron emission sources that use miniaturized RF matching boxes are ultimately unsuitable for long-term and stable electron emission.

### DETAILED DESCRIPTION OF THE INVENTION

In order to solve the aforementioned problems, the present invention aims to provide a durable electron emission source that operates stably over a long period of time without using a filament or an ICP-based electron emission source.

The electron emission source according to the present invention, designed to achieve the aforementioned technical objectives, comprises: a housing provided with a gas inlet pipe for introducing an inert gas into an internal space for plasma generation; a cathode electrode mounted inside the housing, the cathode electrode having a hemispherical shape and being composed of a metallic material; a power supply unit connected to the cathode electrode; and an anode electrode mounted inside the housing at a position facing the cathode electrode, the anode electrode having an internal space formed in a conical shape, composed of a ceramic dielectric material, and including an electron emission port positioned at the apex of the conical shape, which corresponds to the rotational center of the inner surface of the hemispherical cathode electrode, wherein the internal space of the conical shape functions as a plasma chamber, and electrons generated by a capacitively coupled plasma (CCP) between the cathode and anode electrodes are emitted through the electron emission port of the anode electrode.

In the electron emission source according to the above-described feature of the present invention, it is preferable that the rotational center of the hemispherical cathode electrode is aligned with a position corresponding to the electron emission port of the anode electrode, or a position corresponding to an area surrounding the electron emission port.

In the electron emission source according to the above-described feature of the present invention, it is preferable that the power supply unit comprises an RF power supply unit for supplying RF power to generate plasma, and a DC power supply unit for supplying DC power to provide energy to the electrons in the plasma so that they can escape through the electron emission port, thereby applying the RF power and DC power to the cathode electrode.

In the electron emission source according to the above-described feature of the present invention, it is preferable that the hemispherical shape of the DC power supply unit that supplies DC power is made of a heat-resistant metal material, so that it can be used for a prolonged period without the need for cooling water, thereby eliminating the inconvenience of a cooling function.

In the electron emission source according to the above-described feature of the present invention, it is preferable that the DC power supply unit provides a negative DC voltage in the range of 0 to 100 volts, such that electrons having an energy of 0 to 100 eV are emitted through the electron emission port of the electron emission source.

In the electron emission source according to the above-described feature of the present invention, it is preferable that the ceramic dielectric material constituting the anode electrode is an insulating material having dielectric properties, and is composed of one of various heat-resistant ceramics such as alumina (Al₂O₃), zirconia (ZrO₂), yttria (Y₂O₃), yttria-stabilized zirconia (YSZ), magnesia (MgO₂), boron nitride (BN), quartz, or Pyrex.

In the electron emission source according to the above-described feature of the present invention, it is preferable that the electron emission source may further comprise a plasma backflow prevention module mounted at the end of the gas inlet pipe on the plasma chamber side, wherein the plasma backflow prevention module is configured to prevent plasma in the plasma chamber from flowing back into the gas inlet pipe, and is composed of a filter having fine pores, which is manufactured by sintering micro-sized or nano-sized powders.

The electron emission source according to the present invention employs CCP plasma and incorporates newly designed shapes and materials for the cathode and anode electrodes. As a result, compared to conventional ICP plasma-based electron emission sources, it provides enhanced durability that enables long-term operation without thermal degradation caused by plasma heat.

In addition, the electron emission source according to the present invention is capable of durable operation without using the cooling water supply. Compared to conventional electron emission sources using ICP plasma, the electron emission source according to the present invention can operate stably over a long period of time without plasma extinction due to disrupting the RF matching, even when the temperature of the electrodes increases. Furthermore, since the electron emission source according to the present invention does not require a separate power supply for electron focusing in the anode electrode, it allows for compact and miniaturized construction.

Moreover, the electron emission source according to the present invention can be used to neutralize charging that may cause damage to the substrate due to the accumulation of positive charges during ion beam irradiation or ion implantation processes. Accordingly, by utilizing the electron emission source, charging generated during ion beam irradiation or ion implantation can be neutralized, and as a result, the substrate subjected to the ion beam can be protected. Furthermore, the electron emission source according to the present invention may be employed to neutralize substrate charging induced by the impact of ions, wherein the ions are accelerated toward the substrate by receiving energy from plasma generated at a location spaced from the substrate.

Furthermore, the electron emission source according to the present invention may serve as an auxiliary electron supply source within the plasma, thereby assisting in gas dissociation and increasing plasma density. Additionally, since the electron emission source functions as an additional electron supplier, it can extend the operable pressure range of the plasma to lower working pressures.

### BRIEF DESCRIPTION OF THE DRAWINGS

FIG. 1 is a schematic diagram illustrating a neutralization process using an electron emission source during ion beam irradiation onto a target or substrate according to conventional techniques.

FIG. 2 is a schematic cross-sectional view of an electron emission source according to a preferred embodiment of the present invention.

FIGS. 3A and 3B are a perspective view and a side view, respectively, of a hemispherical cathode electrode in the electron emission source according to the preferred embodiment of the

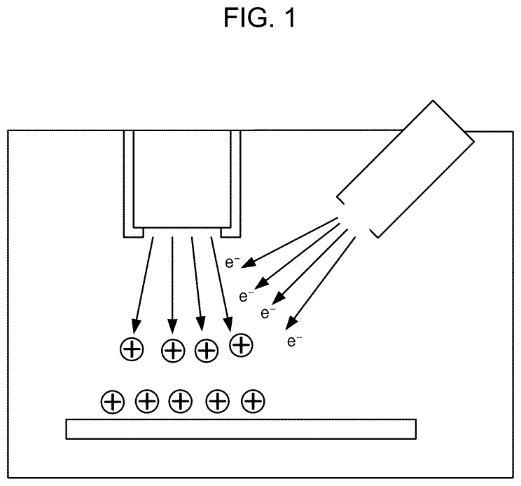

### Present Invention.

FIGS. 4A and 4B are a perspective view and a side view, respectively, of a conical anode electrode having a conical internal space in the electron emission source according to the preferred embodiment of the present invention.

FIG. 5 is a photograph showing the emission of electron beams from the electron emission source according to the preferred embodiment of the present invention.

### BEST MODE FOR CARRYING OUT THE INVENTION

Hereinafter, the structure and operation of the electron emission source according to the preferred embodiment of the present invention will be described in detail with reference to the accompanying drawings.

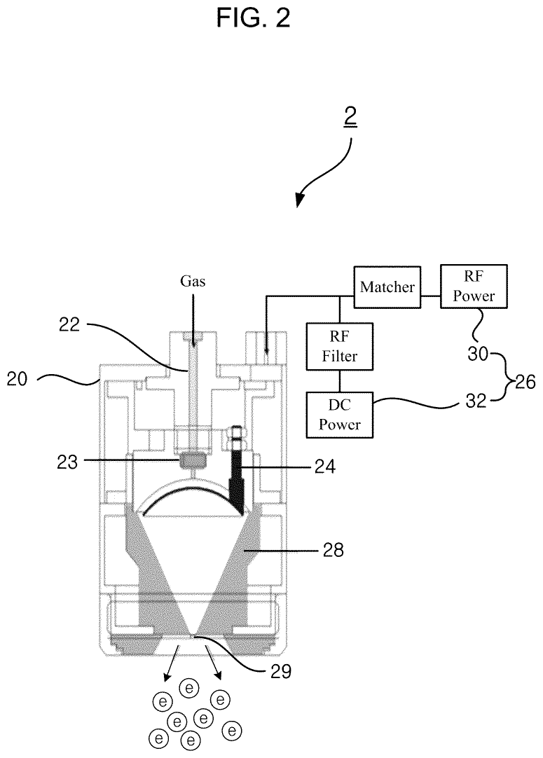

FIG. 2 is a schematic cross-sectional view of an electron emission source according to a preferred embodiment of the present invention.

Referring to FIG. 2, the electron emission source 2 according to the present invention is a source employing CCP (Capacitively Coupled Plasma), and comprises a source housing 20, a gas inlet pipe 22, a cathode electrode 24, an anode electrode 28, and a power supply unit 26. The cathode electrode 24 and the anode electrode 28 are mounted within the internal space of the source housing so as to face each other. The cathode electrode 24 is formed in a hemispherical shape, and the anode electrode 28 has an internal space formed in a conical shape. The power supply unit 26 is connected to the cathode electrode 24.

The gas inlet pipe 22 is provided in a predetermined region of the source housing to inject an inert gas into the internal space of the housing for plasma generation. Through the gas inlet pipe, the inert gas can be supplied into the interior of the source housing.

The power supply unit 26 is connected to the cathode electrode and is configured to apply RF power and DC power to the cathode electrode. The power supply unit 26 includes an RF power supply unit 30 and a DC power supply unit 32. The RF power supply unit 30 is configured to supply RF power for plasma generation. By supplying RF power to the cathode electrode, the RF power supply unit 30 can generate CCP plasma. The DC power supply unit 32 is configured to supply DC power to allow electrons in the plasma to escape. The DC power supply unit 32 may provide a negative DC voltage in the range of 0 to 100 volts. As a result, the electron emission source can emit electrons having an energy of 0 to 100 eV through the electron emission port.

The cathode electrode is composed of a metallic material formed in a hemispherical shape. When RF power is applied to the cathode electrode, CCP plasma can be generated. In a state where plasma is generated, if an additional negative DC power is applied to the cathode electrode, electrons in the plasma can be emitted. At this time, the cathode electrode is subjected to heat due to ion collisions, and therefore, a cooling function for the cathode electrode is required. However, unlike in an ICP plasma system, in which the plasma is extinguished due to the disruption of RF matching caused by heating of the coil, a CCP plasma system exhibits a relatively lower degree of disruption of RF matching even when the coil is heated, thereby allowing continuous and long-term operation. Accordingly, the cathode electrode according to the present invention may be configured using a metal material having heat resistance.

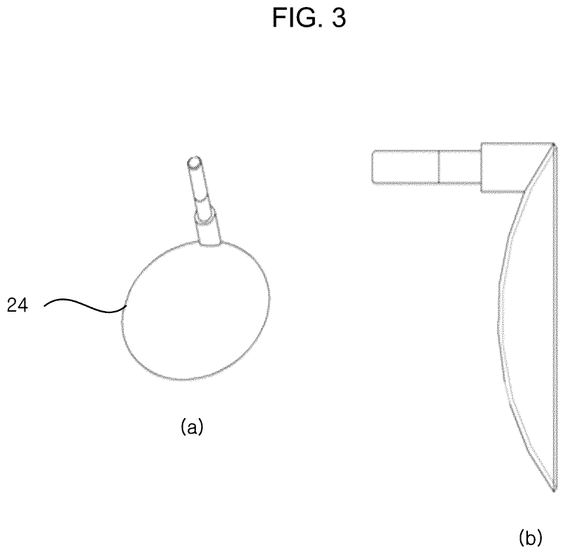

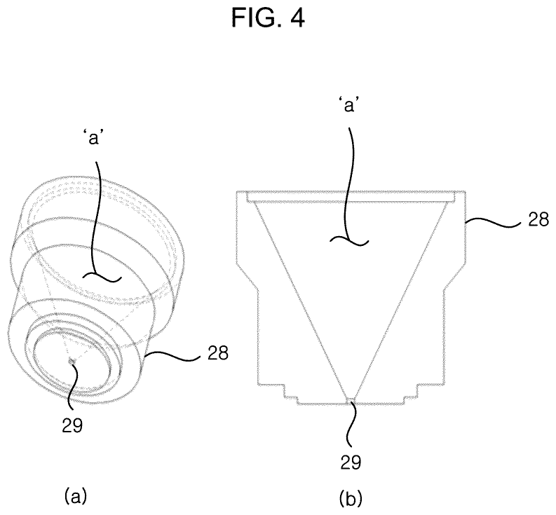

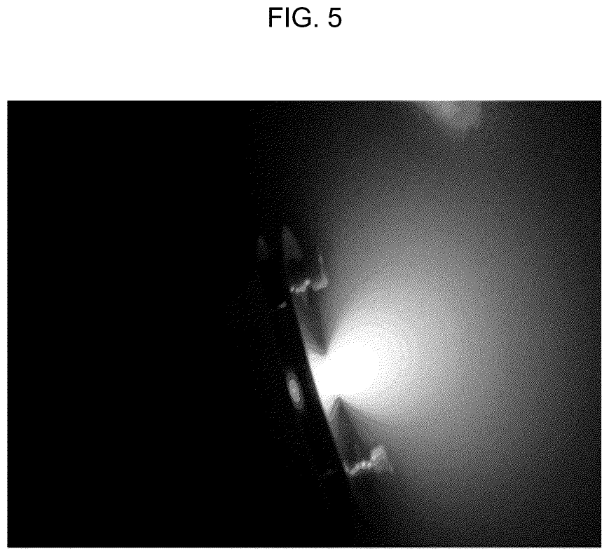

FIGS. 3A and 3B are a perspective view and a side view, respectively, of a hemispherical cathode electrode in the electron emission source according to the preferred embodiment of the present invention. Referring to FIGS. 3A and 3B, when a negative DC power is additionally applied to the cathode electrode through an RF filter, the electrode operates in an operation mechanism that allows electrons in the plasma to be subjected to a hemispherical electric field force directed toward the electron emission port. At this time, since the interior of the plasma is in an electron-rich state, the inner surface of the anode electrode, which is made of a conical ceramic dielectric, experiences temporary adsorption of electron charges due to the DC field shaped in a hemispherical form. As a result of such temporary adsorption of electron charges, negative charges are accumulated, and the electrons within the plasma are subjected to an appropriate repulsive force from the negative charges accumulated on the ceramic wall of the anode electrode. The repulsive force acting on the electrons in the plasma is stronger than the negative charges adsorbed on the anode electrode. In addition to the aforementioned repulsive force, a conical-shaped DC electric field, centered at the rotational center of the hemispherical cathode electrode, acts on the electrons within the plasma chamber. Accordingly, the electrons in the plasma chamber are accelerated along the path focused toward the electron emission port located at the apex of the conical anode electrode, and ultimately, the electrons can escape through this path via the electron emission port.

At this time, it is preferable that the additional negative DC voltage applied to the cathode electrode for electron emission is in the range of 0 to 100 V. Electrons subjected to this voltage acquire an energy of 0 to 100 eV and are emitted from the electron emission port of the electron emission source to travel outward.

Meanwhile, the rotational center of the hemispherical cathode electrode is positioned to correspond to the electron emission port 29 located at the apex of the conical-shaped ceramic dielectric of the anode electrode. With this structure, the electric field acting on the electron beam can be focused such that the electron emission port serves as the exit for electrons within the chamber.

The anode electrode 28 is composed of a ceramic dielectric having an internal space formed in a conical shape. The anode electrode 28 includes an electron emission port 29 at the center point of the bottom of the conical internal space, i.e., at the apex of the conical shape. The internal space of the conical anode electrode can function as a plasma chamber. FIGS. 4A and 4B are a perspective view and a side view, respectively, of the anode electrode having a conical internal space in the electron emission source according to the preferred embodiment of the present invention.

The anode electrode 28 may be composed of an insulating material capable of appropriately accommodating charge accumulation on its surface when electron adsorption occurs. In addition, the anode electrode 28 may be formed of a material having heat resistance to withstand the temperature rise caused by the internal plasma. Examples of suitable materials having such properties include dielectric ceramic insulators with heat resistance, such as alumina (Al₂O₃), zirconia (ZrO₃), yttria (Y₂O₃), magnesia (MgO₂), yttria-stabilized zirconia (YSZ), boron nitride (BN), quartz, and Pyrex.

In the electron emission source according to the present invention having the above-described configuration, when an inert gas is introduced through the gas inlet pipe and RF power is applied to the cathode electrode, the inert gas introduced into the chamber is electrically ionized within the conical plasma chamber to generate and sustain plasma. At this time, additional DC power is applied to the cathode electrode, to which RF power is already applied, thereby maintaining the plasma in a negatively DC-floating state. As a result, additional energy is provided to the electrons in the plasma state within the chamber, enabling the electrons to escape and travel through the electron emission port.

Meanwhile, as described above, when an additional negative DC field is applied to maintain the plasma in a floating state, the electrons in the plasma tend to escape from the plasma region. As a result, electrons may also backflow into the gas inlet pipe through which the gas is introduced, potentially leading to the formation of a plasma stream inside the gas inlet pipe. To prevent the formation of such a plasma stream connected to the plasma within the gas inlet pipe, a plasma backflow prevention module 23 may be installed. The plasma backflow prevention module 23 may be installed at the end of the gas inlet pipe 22 on the plasma chamber side. The plasma backflow prevention module 23 may be configured to allow the gas to flow through the gas inlet pipe while blocking the passage of electrons. The plasma backflow prevention module may be implemented by forming a portion of the gas inlet pipe as a complex passage having fine holes, or by using a filter fabricated by sintering micro-sized or nano-sized powder.

FIG. 5 is a photograph showing the emission of electrons from the electron emission source according to the preferred embodiment of the present invention. Referring to FIG. 5, the electron emission source of the present invention allows electrons having an energy of 0 to 100 eV to escape and travel from the electron emission source through the electron emission port provided in the anode electrode.

While the present invention has been described above with reference to preferred embodiments, it is to be understood that these embodiments are merely illustrative and not intended to limit the scope of the invention. Various modifications and applications not specifically described herein may be made by those skilled in the art without departing from the essential spirit and scope of the invention. Such modifications and applications shall be interpreted as falling within the scope of the invention as defined by the appended claims.

What is claimed is:

1. An electron emission source comprising:
a housing provided with a gas inlet pipe configured to introduce an inert gas into an internal space for plasma generation;
a cathode electrode mounted inside the housing, the cathode electrode having a hemispherical shape and being made of a metallic material;
a power supply unit connected to the cathode electrode; and
an anode electrode mounted inside the housing at a position facing the cathode electrode, the anode electrode having an internal space formed in a conical shape and composed of a ceramic dielectric material, the anode electrode including an electron emission port formed at an apex of the conical shape, the conical internal space functioning as a plasma chamber,
wherein RF power is supplied to the cathode electrode to generate a capacitively coupled plasma (CCP) in the plasma chamber, and electrons are emitted through the electron emission port of the anode electrode using the CCP.

2. The electron emission source according to claim 1, wherein a rotational center of the hemispherical cathode electrode is aligned with a position corresponding to the electron emission port of the anode electrode, or a position corresponding to an area surrounding the electron emission port.

3. The electron emission source according to claim 1, wherein the power supply unit comprises:
an RF power supply unit configured to supply RF power for plasma generation; and
a DC power supply unit configured to supply DC power for enabling electrons in the plasma to escape,
wherein the RF power and the DC power are combined and applied to the cathode electrode.

4. The electron emission source according to claim 3, wherein the DC power supply unit provides a negative DC voltage in a range of 0 to 100 volts.

5. The electron emission source according to claim 1, wherein the ceramic dielectric material constituting the anode electrode is an insulating material having dielectric properties, and is composed of one selected from the group consisting of alumina (Al₂O₃), zirconia (ZrO₂), yttria (Y₂O₃), magnesia (MgO₂), yttria-stabilized zirconia (YSZ), boron nitride (BN), quartz, and Pyrex.

6. The electron emission source according to claim 1, wherein the cathode electrode, serving as the electrode for generating plasma, is composed of a heat-resistant metal capable of withstanding the plasma temperature, and
wherein no cooling water is supplied to the cathode electrode.

7. The electron emission source according to claim 1, further comprising a plasma backflow prevention module installed at an end of the gas inlet pipe on the plasma chamber side,
wherein the plasma backflow prevention module is configured to prevent plasma in the plasma chamber from backflowing into the gas inlet pipe.

8. The electron emission source according to claim 7, wherein the plasma backflow prevention module comprises a filter having fine pores, the filter being formed by sintering micro-or nano-sized powder.

9. The electron emission source according to claim 1, wherein the gas inlet pipe is configured to supply an inert gas.
